(19) United States
(12) Patent Application Publication
(10) Pub. No.: US 2019/0002191 A1
(43) Pub. Date: Jan. 3, 2019

(54) APPARATUS, SYSTEM, AND METHOD FOR STORING OPTICAL COMPONENTS

(71) Applicant: Intel Corporation, Santa Clara, CA (US)

(72) Inventor: Amanuel M. Abebaw, Chandler, AZ (US)

(21) Appl. No.: 15/638,671

(22) Filed: Jun. 30, 2017

(51) Int. Cl. B65D 85/38; G02B 27/00; B65D 21/02; B65D 25/10; B65G 47/91; B65G 47/92

(52) U.S. Cl. CPC B65D 85/38; G02B 27/0006; B65D 21/0209; H01L 21/67144; B65G 47/91; B65G 47/92; B65D 25/10

(57) ABSTRACT

An optical component storage tray may define a plane. The tray may include a first side. The tray may include a second side. The first side and second side may be located on opposite sides of the plane. The tray may include a plurality of sockets. The plurality of sockets may be positioned on the first side. The plurality of sockets may include engaging features. The plurality of sockets may include a pocket. The pocket may be configured to receive an optical component. The tray may include a plurality of plugs. The plurality of plugs may be positioned on the second side. The plurality of plugs may include mating features. The mating features and the engaging features may be configured to intermesh. The tray may be formed from a composite material. The composite material may include a polycarbonate matrix. The composite material may include a dispersed carbon phase.

### BACKGROUND

Optical components (e.g., lenses, prisms, photosensors, or the like) may be susceptible to damage (e.g., scratches) or contamination (e.g., dust) from a wide variety of sources. The optical components may be stored and/or transported in gel packs. Gel packs may be expensive, require modification of manufacturing processes, and have a low part density (e.g., the number of optical components per unit area).

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates an example of an optical component storage tray.

FIG. 2 illustrates a different portion of the optical component storage tray of FIG. 1.

FIG. 3 illustrates a different portion of the optical component storage tray of FIG. 1.

FIG. 4 illustrates a portion of an optical device manufacturing assembly.

FIG. 5 illustrates a different portion of the optical device manufacturing assembly of FIG. 4.

FIG. 6 illustrates a method for using the optical component storage tray of FIGS. 1-3.

### DETAILED DESCRIPTION

The present inventors have recognized, among other things, that a problem to be solved may include storing and transporting optical components such that the optical components are less susceptible to damage. The present inventors have recognized, among other things, that a problem to be solved may include storing and transporting optical components such that the optical components are less susceptible to contamination. The present inventors have recognized, among other things, that a problem to be solved may include storing and transporting optical components such that the optical components are less susceptible to moving out of the position in which they were stored. The present inventors have recognized, among other things, that a problem to be solved may include storing and transporting optical components such that the optical components are less susceptible to electrostatic discharge.

The present subject matter may help provide a solution to these problems, such as by providing an optical component storage tray. The optical component storage tray may be used for transporting the optical components. The optical component storage tray may define a plane. The tray may include a top side. The top side may be a first side. The tray may include a bottom side. The bottom side may be a second side. The top side and bottom side may be located on opposite sides of the plane. The tray may include a plurality of sockets. The plurality of sockets may be positioned on the top side. The plurality of sockets may include engaging features. The plurality of sockets may include a pocket. The pocket may be configured to receive an optical component. The tray may include a plurality of plugs. The plurality of plugs may be positioned on the bottom side. The plurality of plugs may include mating features. The mating features and the engaging features may be configured to intermesh. The tray may be formed from a composite material. The composite material may include a polycarbonate matrix. The composite material may include a dispersed carbon phase.

The present subject matter may help provide a solution to these problems, such as by securely retaining the optical component within the pocket. Securely retaining the optical component may include entirely or substantially inhibiting the movement of the optical component in relation to the tray. Securely retaining the optical component may prevent undesirable movement of the optical component. Movement of the optical component may damage the optical component. Movement of the optical component may result in the optical component not being in the position in which the optical component was stored. The present subject matter may help provide a solution to these problems, such as by forming the tray from the composite material. The composite material may prevent a build-up of electrostatic charge. Preventing the build-up of electrostatic charge may prevent the attraction of foreign material to the optical components stored within the tray. Preventing the build-up of electrostatic charge may prevent an electrostatic discharge to the optical component. The present subject matter may help provide a solution to these problems, such as by allowing a greater number of optical components to be stored in a specific area (e.g., increased part density). The part density may increase due to providing sufficient retention and protection of the optical components, in an area less than what is required for gel packs.

Aspect 1 can include or use subject matter (such as an apparatus, a system, a device, a method, a means for performing acts, or a device readable medium including instructions that, when performed by the device, can cause the device to perform acts), such as can include or use an optical component storage tray (“the tray”). The tray may define a plane. The tray may include a top side. The top side may be a first side. The tray may include a bottom side. The bottom side may be a second side. The top side and bottom side may be located on opposite sides of the plane. The tray may include a plurality of sockets. The plurality of sockets may be positioned on the top side. The plurality of sockets may include engaging features. The plurality of sockets may include a pocket. The pocket may be configured to receive an optical component. The tray may include a plurality of plugs. The plurality of plugs may be positioned on the bottom side. The plurality of plugs may include mating features. The mating features and the engaging features may be configured to intermesh. The tray may be formed from a composite material. The composite material may include a polycarbonate matrix. The composite material may include a dispersed carbon phase.

Aspect 2 can include or use, or can optionally be combined with the subject matter of Aspect 1, to optionally include or use that the mating features may be male and the engaging features may be female. The mating features may be female and the engaging features may be male.

Aspect 3 can include or use, or can optionally be combined with the subject matter of one or any combination of Aspects 1 or 2 to optionally include or use that the mating features may include a pin. The engaging features may include a recess.

Aspect 4 can include or use, or can optionally be combined with the subject matter of one or any combination of Aspects 1 through 3 to optionally include or use that the dispersed carbon phase may include carbon fibers.

Aspect 5 can include or use, or can optionally be combined with the subject matter of Aspect 4 to optionally include or use that the carbon fibers may constitute 5 to 15 percent of the volume of the composite material.

Aspect 6 can include or use, or can optionally be combined with the subject matter of one or any combination of Aspects 1 through 5 to optionally include or use that the dispersed carbon phase may include carbon nanotubes.

Aspect 7 can include or use, or can optionally be combined with the subject matter of Aspect 6 to optionally include or use that the carbon nanotubes may constitute 1 to 10 percent of the volume of the composite material.

Aspect 8 can include or use, or can optionally be combined with the subject matter of one or any combination of Aspects 1 through 7 to optionally include or use that the composite material includes polytetrafluoroethylene (“PTFE”).

Aspect 9 can include or use, or can optionally be combined with the subject matter of Aspect 8 to optionally include or use that the PTFE may constitute 1.5 to 2.5 percent of the volume of the composite material.

Aspect 10 can include or use, or can optionally be combined with the subject matter of one or any combination of Aspects 1 through 9 to optionally include or use that the polycarbonate may constitute 70 to 90 percent of the volume of the composite material.

Aspect 11 can include or use, or can optionally be combined with the subject matter of one or any combination of Aspects 1 through 10 to optionally include or use that the optical component may include a compound parabolic concentrator, polarizing beam splitter, metallic RF shield, RGB die, CMOS die, MEMS, lens, and/or lens holder.

Aspect 12 can include or use, or can optionally be combined with the subject matter of one or any combination of Aspects 1 through 11 to optionally include or use that each of the plurality of plugs may be configured to engage with the optical component.

Aspect 13 can include or use subject matter (such as an apparatus, a system, a device, a method, a means for performing acts, or a device readable medium including instructions that, when performed by the device, can cause the device to perform acts), such as can include or use an optical device manufacturing assembly. The optical device manufacturing assembly may include a pick and place machine. The pick and place machine may be configured to couple with an optical component. The optical device manufacturing assembly may include a stack of two or more optical component storage trays, including a first tray and a second tray. The optical component storage trays may include a top side. The top side may be a first side. The optical component storage trays may include a bottom side. The bottom side may be a second side. The top side and bottom side may be located on opposite sides of a plane defined by the tray.

The optical component storage trays may include a plurality of sockets. The plurality of sockets may be positioned on the top side. The plurality of sockets may include engaging features. The plurality of sockets may include a pocket. The pocket may be configured to receive individual optical components. The optical component storage trays may include a plurality of plugs. The plurality of plugs may be positioned on the bottom side. The plurality of plugs may include mating features. The mating features and the engaging features may be configured to intermesh. The tray may be formed from a composite material. The composite material may include a polycarbonate matrix. The composite material may include a dispersed carbon phase. The optical component storage trays may include an optical component. The optical component may be positioned in each of the pockets. The optical component storage trays may include a target surface having a target position. The pick and place machine may be configured to transport the optical component. The pick and place machine may be configured to transport the optical component from the pocket to the target position.

Aspect 14 can include or use, or can optionally be combined with the subject matter of Aspect 13, to optionally include or use that the mating features may be male and the engaging features may be female.

Aspect 15 can include or use, or can optionally be combined with the subject matter of one or any combination of Aspects 13 or 14 to optionally include or use that the plurality of plugs of the second tray may be intermeshed with the plurality of sockets of the first tray. The intermeshing of the plurality of plugs with the plurality of pockets may retain the optical component within each of the pockets.

Aspect 16 can include or use, or can optionally be combined with the subject matter of one or any combination of Aspects 13 through 15 to optionally include or use a retaining feature. The retaining feature may extend from each of the plurality of plugs. The retaining feature may be configured to engage with the optical component.

Aspect 17 can include or use, or can optionally be combined with the subject matter of one or any combination of Aspects 13 through 16 to optionally include or use that the dispersed carbon phase may include carbon fibers.

Aspect 18 can include or use, or can optionally be combined with the subject matter of one or any combination of Aspects 13 through 17 to optionally include or use that the dispersed carbon phase may include carbon nanotubes.

Aspect 19 can include or use, or can optionally be combined with the subject matter of one or any combination of Aspects 13 through 18 to optionally include or use that the optical component may include a compound parabolic concentrator, polarizing beam splitter, metallic RF shield, RGB die, CMOS die, MEMS, lens, and/or lens holder.

Aspect 20 can include or use subject matter (such as an apparatus, a system, a device, a method, a means for performing acts, or a device readable medium including instructions that, when performed by the device, can cause the device to perform acts), such as can include or use a method for using an optical component storage tray. The method may include retaining an optical component in a pocket of a first optical component storage tray. The method may include removing a second optical component storage tray. The second tray may be stacked upon the first tray. The method may include picking the optical component from a first position. The first position may be within the pocket. The method may include moving the optical component to a second position. The method may include placing the optical component at the second position.

Aspect 21 can include or use, or can optionally be combined with the subject matter of Aspect 20, to optionally include or use that removing the second optical component storage tray may demesh engaging features of a plurality of sockets of the second tray from mating features of a plurality plugs of the first tray. Demeshing may allow access to the plurality of sockets of the first tray.

Aspect 22 can include or use, or can optionally be combined with the subject matter of one or any combination of Aspects 20 or 21 to optionally include or use that picking the optical component from the first position may include grasping the optical component with mechanical pincers.

Aspect 23 can include or use, or can optionally be combined with the subject matter of one or any combination of Aspects 20 through 22 to optionally include or use that picking the optical component from the first position may include applying a vacuum to the optical component.

Aspect 24 can include or use, or can optionally be combined with the subject matter of one or any combination of Aspects 20 through 23 to optionally include or use that picking the optical component from the first position may include coupling a magnet to the optical component.

Aspect 25 can include or use, or can optionally be combined with the subject matter of Aspect 24 to optionally include or use that placing the optical component at the second position may include generating a magnetic field, thereby decoupling the magnet from the optical component.

Aspect 26 can include or use, or can optionally be combined with any portion or combination of any portions of any one or more of Aspects 1 through 25 to include or use, subject matter that can include means for performing any one or more of the functions of Aspects 1 through 25, or a machine-readable medium including instructions that, when performed by a machine, cause the machine to perform any one or more of the functions of Aspects 1 through 25.

Each of these non-limiting examples may stand on its own, or may be combined in various permutations or combinations with one or more of the other examples.

This overview is intended to provide an overview of subject matter of the present patent application. It is not intended to provide an exclusive or exhaustive explanation of the invention. The detailed description is included to provide further information about the present patent application.

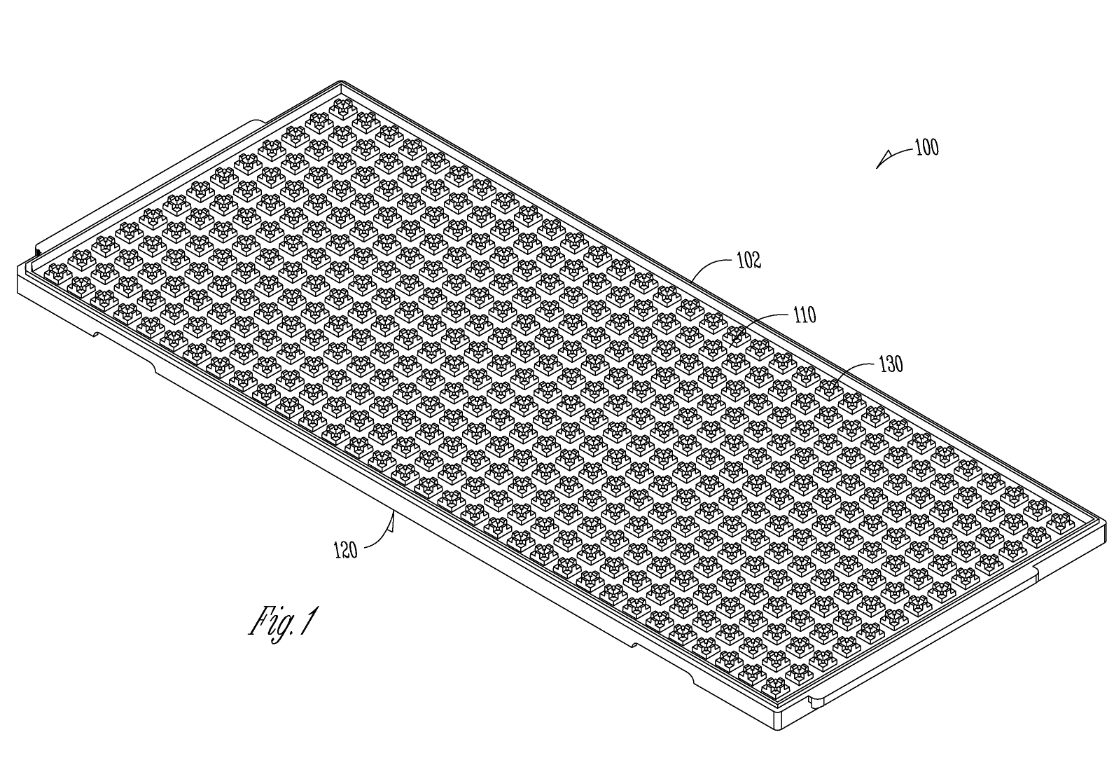

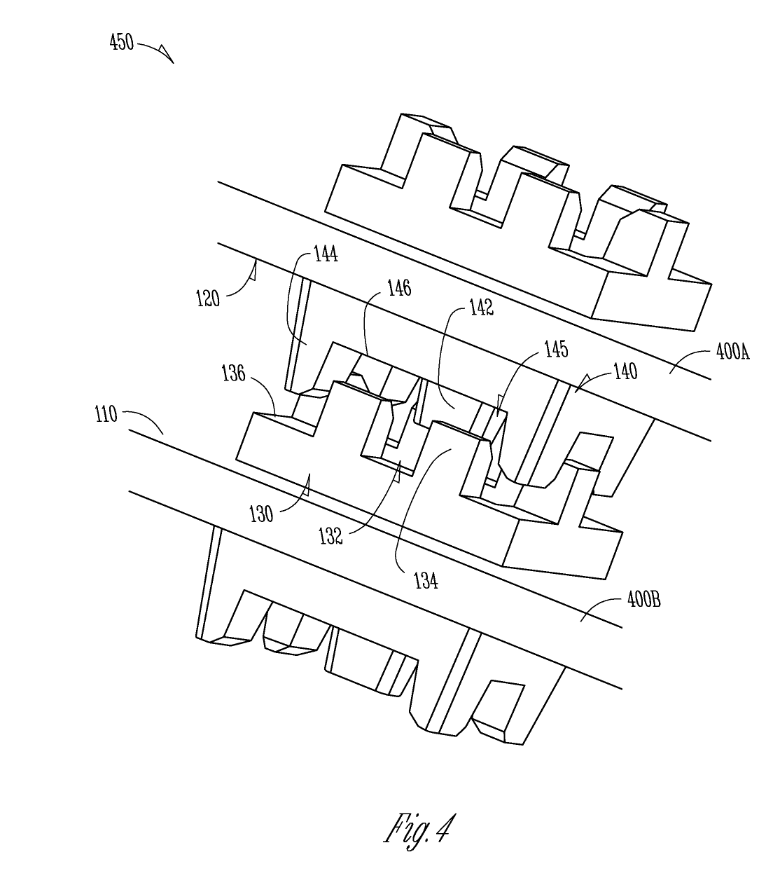

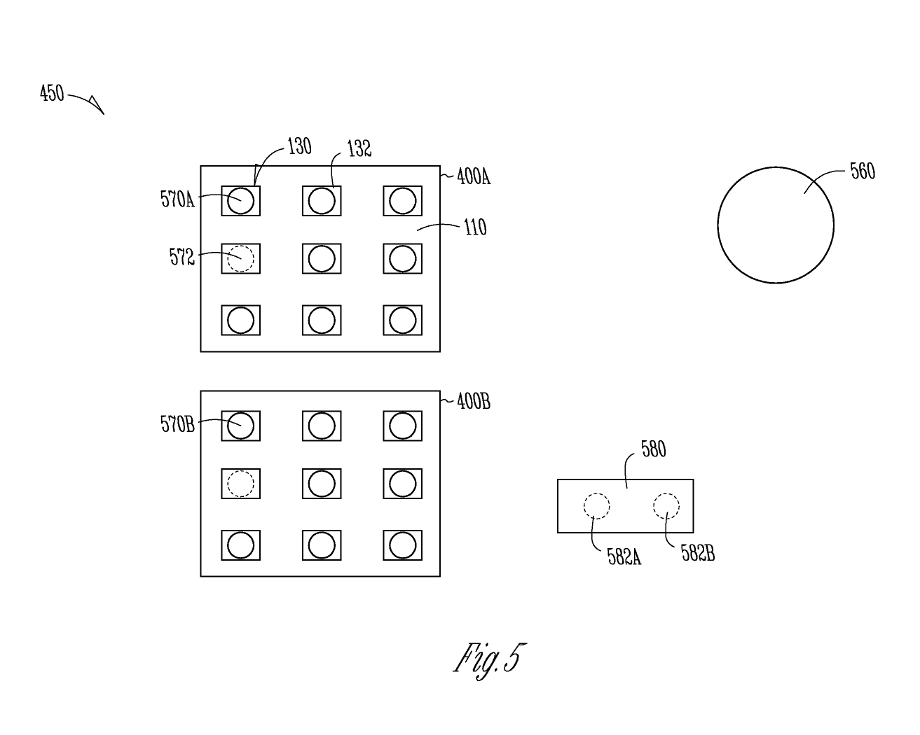

FIG. 1 illustrates an example of an optical component storage tray 100 (“the tray 100”). The tray 100 may define a plane. The tray 100 may include a top side 110. The top side may be a first side. The tray 100 may include a bottom side 120. The bottom side may be a second side. The top side 110 and the bottom side 120 may be located on opposite sides of the plane. The tray 100 may include a plurality of sockets 130. The tray may include a plurality of plugs (shown in FIGS. 3 and 4). The tray 100 may be configured to couple with a JEDEC tray. The tray 100 may include features that allow the tray 100 to couple with the JEDEC tray.

The tray 100 may be formed from a composite material 102. The composite material 102 may include a polycarbonate matrix. The composite material 102 may include a dispersed carbon phase. The polycarbonate may constitute 70 to 90 percent of the volume of the composite material 102. The dispersed carbon phase may include carbon fibers. The carbon fibers may constitute 5 to 15 percent of the volume of the composite material 102. The dispersed carbon phase may include carbon nanotubes. The carbon nanotubes may constitute 1 to 10 percent of the volume of the composite material 102. The composite material 102 may include polytetrafluoroethylene (“PTFE”). The PTFE may constitute 1.5 to 2.5 percent of the volume of the composite material 102.

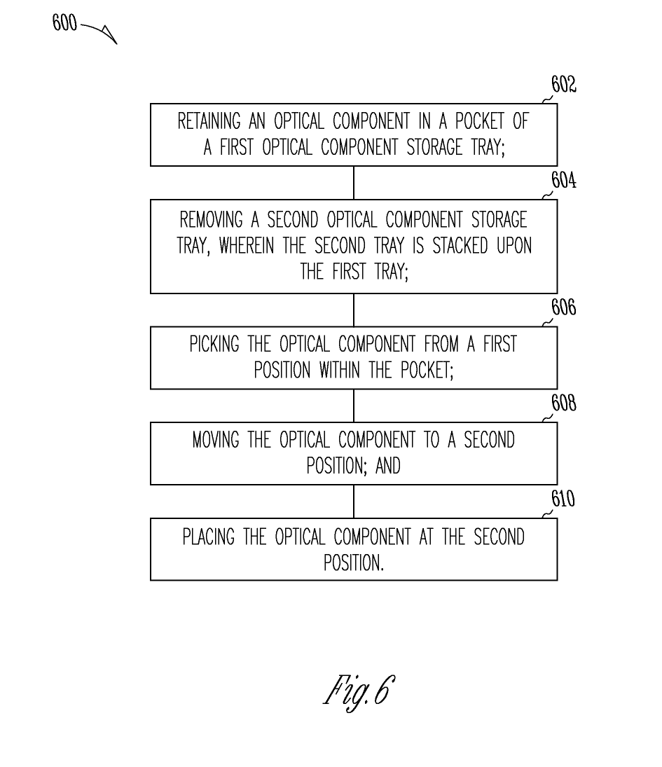

The composite material 102 may prevent the build-up of electrostatic charge (e.g., an excess electrical charge) on the tray 100 or on optical components (e.g., the optical component 570B of FIG. 5) contained within the tray 100. The composite material 102 may allow for electrical conduction within the tray 100, thereby reducing the ability for a charge to accumulate within the tray 100. The composite material 102 may substantially inhibit electrostatic induction. The separation of charged particles within the composite material 102 may be limited by the polycarbonate matrix and the dispersed carbon phase, thereby preventing the build-up of an electrostatic charge within the composite material 102. The combination of the polycarbonate matrix (e.g., an insulator) with the dispersed carbon phase (e.g., a conductor) may prevent any electrical charges that would build up, by allowing for the charges to be neutralized. The composite material 102 may prevent the electrostatic induction of foreign material (e.g., dust) to the tray 100 or the optical components stored therein. The composite material 102 may be injection moldable. The composite material 102 may give rigidity and assist in holding optical components in the required size and flatness tolerance.

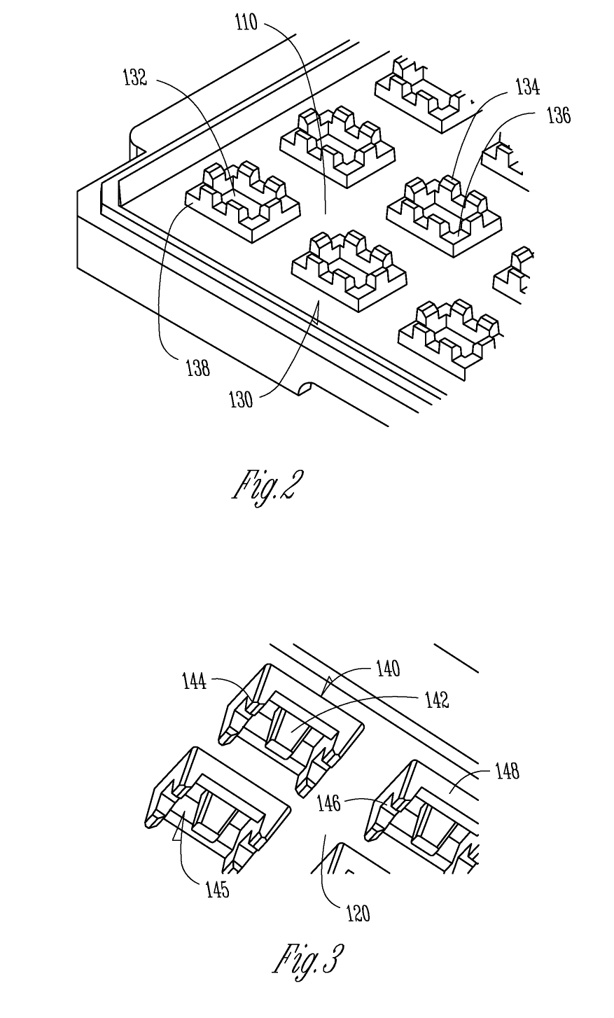

FIG. 2 illustrates a different portion of the optical component storage tray 100 of FIG. 1. The top side 110 may include the plurality of sockets 130. The plurality of sockets 130 may include sidewalls 138 that extend from the top surface 110. The plurality of sockets 130 may each include a pocket 132. The sidewalls 138 of the plurality of sockets 130 may define the pocket 132. The plurality of sockets 130 may each include engaging features 134 and 136. The engaging features 134 and 136 may be female features. The engaging features 134 and 136 may include a recess. The engaging features 134 and 136 may be arranged on the periphery of each of the plurality of sockets 130. The engaging features 134 and 136 may protrude normal to a first (e.g., top) surface of the sidewalls 138. The engaging features 134 and 136 may protrude from the top surface 110. The engaging features 134 and 136 may include a series of protrusions and recesses. The plurality of sockets 130 may be arranged in a grid on the top surface 110. Each of the plurality of sockets 130 may be spaced at a first distance or at a second distance from an adjacent socket.

As shown in FIG. 2, the plurality of sockets 130 may be generally rectangular in shape. However, the present subject matter is not so limited. The plurality of sockets 130 may be any geometric (e.g., polygonal) or amorphous shape. As shown in FIG. 2, the pocket 132 may be generally rectangular in shape. However, the present subject matter is not so limited. The pocket 132 may be any geometric or amorphous shape. The pocket 132 may be configured to receive an optical component (e.g., the optical component 570A of FIG. 5). The pocket 132 may be configured to conform (e.g., the pocket 132 may yield to an applied force, such as mating an optical component with the pocket 132) to the shape of the optical component. The pocket 132 may be oversized (e.g., have a clearance) in relation to the dimensions of the optical component. In an example, the pocket 132 may be oversized by 250 micrometers in relation to the dimensions of the optical component. Positioning an optical component within the pocket 132 may prevent, or substantially inhibit, movement of the optical component in relation to the tray 100.

FIG. 3 illustrates a different portion of the optical component storage tray 100 of FIG. 1. The tray 100 may include the bottom surface 120. The bottom surface 120 may include a plurality of plugs 140. The plurality of plugs 140 may each include a retaining feature 142. The retaining feature 142 may be a finger that extends from a plug of the plurality of plugs 140. The retaining feature 142 may be configured to engage with an optical component (not shown). The engagement of the mating feature 142 with the optical component may prevent the optical component from moving in a vertical direction (e.g., bouncing). Stated another way, the retaining feature 142 may retain (e.g., substantially secure or immobilize) the optical component. The retaining feature 132 may be configured to conform (e.g., the retaining feature 142 may yield to an applied force, such as mating the retaining feature 142 with an optical component) to the shape of the optical component.

The plurality of plugs 140 may include sidewalls 148 that extend from the bottom surface 120. The sidewalls 148 may define a void 145. The retaining feature 142 may define the void 145. The plurality of plugs 140 may each include mating features 144 and 146. The mating features 144 and 146 may be male features. The mating features 144 and 146 may include a pin. The mating features 144 and 146 may be arranged on the periphery of each of the plurality of plugs 140. The mating features 144 and 146 may protrude normal to a first (e.g., top) surface of the sidewalls 148. The mating features 144 and 146 may protrude from the bottom surface 120. The mating features 144 and 146 may include a series of protrusions and recesses. The plurality of plugs 140 may be arranged in a grid on the bottom surface 120. Each of the plurality of plugs 140 may be spaced at a first distance or at a second distance from an adjacent plug. As discussed herein, the tray 100 may be configured such that the tray 100 is capable of being stacked upon an additional tray 100. The engaging features 134 and 136 (shown in FIGS. 2 and 4) of the plurality of sockets 130, and the mating features 144 and 146 of the plurality of plugs 140, may allow for the tray 100 to be stacked upon another tray 100.

As shown in FIG. 3, the plurality of plugs 140 may be generally rectangular in shape. However, the present subject matter is not so limited. The plurality of plugs 140 may be any geometric (e.g., polygonal) or amorphous shape. As shown in FIG. 3, the void 132 may be an amorphous shape (e.g., resembling a toroid). However, the present subject matter is not so limited. The void 145 may be any geometric or amorphous shape. In an example, wherein the plurality of plugs 140 does not include the retaining feature 132, the void 145 may be generally rectangular in shape.

FIG. 4 illustrates a portion of an optical device manufacturing assembly 450 (“the assembly 450”). The assembly 450 may include a first optical component storage tray 400A (“first tray 400A”). The first tray 400A may be the tray 100. The assembly 450 may include a second optical component storage tray 400B (“second tray 400B”). The second tray 400B may be the tray 100. As discussed herein, the tray 100 (shown in FIGS. 1-3) may be configured such that the tray 100 is capable of being stacked upon an additional tray 100. The engaging features 134 and 136 of the plurality of sockets 130, and the mating features 144 and 146 of the plurality of plugs 140, may allow for the tray 100 to be stacked upon another tray 100. In an example, the first tray 400A and the second tray 400B may be configured to mate with each other. The first tray 400A and the second tray 400B may be configured to stack upon each other. The assembly 450 may include additional trays (e.g., a third or fourth tray, not shown). The additional trays may be configured to mate with each other. The additional trays may be configured to stack upon each other.

The engaging features 134 and 136, and the mating features 144 and 146, may allow for the stacking capability of the first tray 400A upon the second tray 400B (or vice-versa). The engaging features 134 and 136, and the mating features 144 and 146, may be configured to intermesh (e.g., interlock). The intermeshing of the engaging features 134 and 136, and the mating features 144 and 146, may mate (or couple) the first tray 400A with the second tray 400B. The intermeshing of the engaging features 134 and 136, and the mating features 144 and 146, may prevent movement of the first tray 400A with respect to the second tray 400B (e.g., in the directions parallel to the plane defined by the tray 100 of FIGS. 1-3). FIG. 4 shows a distance between the engaging features 134 and 136, and the mating features 144 and 146. However, the engaging features 134 and 136, and the mating features 144 and 146 may be configured to mate, or be in communication with, each other. Stated another way, there may not be a distance between the engaging features 134 and 136, and the mating features 144 and 146.

Stacking the first tray 400A upon the second tray 400B may cause the retaining feature 142 to extend into the pocket 132. In an example, wherein an optical component (not shown) is positioned within the pocket 132, stacking the first tray 400A upon the second tray 400B may cause the retaining feature 142 to engage with the optical component. The plurality of sockets 130 and the plurality of plugs 140 may be configured such that stacking the first tray 400A upon the second tray 400B may protect an optical component (not shown), contained within the pocket 132, from coming into communication with foreign material and/or moving. The plurality of sockets 130 and the plurality of plugs 140 may be configured such that stacking the first tray 400A upon the second tray 400B may seal an optical component within the pocket 132. The plurality of sockets 130 and the plurality of plugs 140 may be configured such that stacking the first tray 400A upon the second tray 400B may retain an optical component within the pocket 132 and/or the void 145. The engaging features 134 and 136, and the mating features 144 and 146, may be configured to allow the protection and/or sealing of the optical component within the pocket 132. The optical component may extend into the void 145 and still be protected and/or sealed from the external environment (or foreign material contained therein).

FIG. 5 illustrates a different portion of the optical device manufacturing assembly 450 of FIG. 4. The assembly 450 may include a pick and place machine 560. The pick and place machine 560 may be configured to couple with a first optical component 570A. The pick and place machine 560 may be configured to couple with a second optical component 570B. The first optical component 570A and/or the second optical component 570B may include a compound parabolic concentrator, polarizing beam splitter, metallic RF shield, RGB die, CMOS die, MEMS, lens, and/or lens holder.

The assembly 450 may include the first tray 400A and the second tray 400B. The first tray 400A and the second tray 400B may include the plurality of sockets 130. Each of the plurality of sockets 130 may include the pocket 132. The first optical component 570A may be positioned within an individual socket of the plurality of sockets 130. The first optical component 570A may be positioned within the pocket 132. Each of the plurality of sockets 130 may include the first optical component 570A or a second optical component 570B.

The assembly 450 may include a target surface 580. The target surface 580 may include a first target position 582A. The target surface 580 may include a second target position 582B. The pick and place machine 560 may be configured to transport the first optical component 570A and/or the second optical component 570B. The pick and place machine 560 may be configured to transport the first optical component 570A from the pocket 132 to the first target position 582A and/or the second target position 582B. The pick and place machine 560 may be configured to transport the second optical component 570A from the pocket 132 to the first target position 582A and/or the second target position 582B. The pick and place machine 560 may be configured to transport each of the optical components contained within the plurality of sockets 130 to a corresponding number of target positions. The assembly 450 may include additional target surfaces having additional target positions. The pick and place machine 560 may be configured to transport the first optical component 570A and/or the second optical component 570B from their respective pockets (e.g., pocket 132) to the additional target positions.

FIG. 6 illustrates a method 600 for using the optical component storage tray 100 of FIGS. 1-3. The method 600 may include at operation 602 retaining an optical component (e.g., the first optical component 570A or the second optical component 570B of FIG. 5) in a pocket (e.g., the pocket 132 of FIGS. 2, 4, and 5) of a first optical component storage tray (e.g., the first tray 400A of FIG. 4). The method 600 may include at operation 604 removing a second optical component storage tray (e.g., the second tray 400B of FIG. 4), wherein the second tray is stacked upon the first tray. The method 600 may include at operation 606 picking (e.g., coupling with) the optical component from a first position within the pocket. The method 600 may include at operation 608 moving the optical component to a second position (e.g., first target position 582A or the second target position 582B of FIG. 5). The method 600 may include at operation 606 placing the optical component at the second position.

The method 600 may also include that removing the second optical component storage tray demeshes engaging features (e.g., the engaging features 134 and 136 of FIGS. 2, 4, and 5) of a plurality of sockets (e.g., the plurality of sockets 130 of FIGS. 1, 2, 4, and 5) of the second tray from mating features (e.g., the mating features 144 and 146 of FIGS. 3, 4, and 5) of a plurality sockets (e.g., the plurality of sockets of FIGS. 3, 4, and 5) of the first tray, thereby allowing access to the plurality of sockets of the first tray.

The method 600 may also include that picking the optical component from the first position includes grasping the optical component with mechanical pincers. The method 600 may also include that picking the optical component from the first position includes applying a vacuum to the optical component. The method 600 may also include that picking the optical component from the first position includes coupling a magnet to the optical component. The method 600 may also include that placing the optical component at the second position includes generating a magnetic field, thereby decoupling the magnet from the optical component. In an example, the attractive forces between the optical component and the magnet may be cancelled out by a magnetic field located near the magnet and the optical component, thereby causing the optical component to decouple from the magnet.

### VARIOUS NOTES

The above description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

The claimed invention is:

1. An optical component storage tray, the tray defining a plane and comprising:
a first side and a second side, wherein the first side and the second side are located on opposite sides of the plane;
a plurality of sockets positioned on the first side, wherein the plurality of sockets includes engaging features and a pocket configured to receive an optical component;
a plurality of plugs positioned on the second side, wherein the plurality of plugs includes mating features;
wherein the mating features and the engaging features are configured to intermesh; and
wherein the tray is formed from a composite material and the composite material includes a polycarbonate matrix and a dispersed carbon phase.

2. The tray of claim 1, wherein the mating features are male and the engaging features are female.

3. The tray of claim 1, wherein the mating features includes a pin and the engaging features include a recess.

4. The tray of claim 1, wherein the dispersed carbon phase includes carbon fibers.

5. The tray of claim 4, wherein the carbon fibers constitute 5 to 15 percent of the volume of the composite material.

6. The tray of claim 1, wherein the dispersed carbon phase includes carbon nanotubes.

7. The tray of claim 6, wherein the carbon nanotubes constitute 1 to 10 percent of the volume of the composite material.

8. The tray of claim 1, wherein the composite material includes polytetrafluoroethylene (“PTFE”).

9. The tray of claim 8, wherein the PTFE constitutes 1.5 to 2.5 percent of the volume of the composite material.

10. The tray of claim 1, wherein the polycarbonate constitutes 70 to 90 percent of the volume of the composite material.

11. The tray of claim 1, wherein the optical component includes a compound parabolic concentrator, polarizing beam splitter, metallic RF shield, RGB die, CMOS die, MEMS, lens, or lens holder.

12. The tray of claim 1, wherein each of the plurality of plugs is configured to engage with the optical component.

13. An optical device manufacturing assembly, comprising:
a pick and place machine configured to couple with an optical component;
a stack of two or more optical component storage trays, including a first tray and a second tray, and wherein the optical component storage trays include:
a first side and a second side, wherein the first side and the second side are located on opposite sides of a plane defined by the tray;
a plurality of sockets positioned on the first side, wherein the plurality of sockets includes engaging features and a pocket configured to receive individual optical components;
a plurality of plugs positioned on the bottom side, wherein the plurality of plugs includes mating features;
wherein the mating features and the engaging features are configured to intermesh; and
wherein the tray is formed from a composite material and the composite material includes a polycarbonate matrix and a dispersed carbon phase;
an optical component positioned in each of the pockets of the plurality of sockets; and
a target surface having a target position, wherein the pick and place machine is configured to transport the optical component from the pocket to the target position.

14. The assembly of claim 13, wherein the mating features are male and the engaging features are female.

15. The assembly of claim 13, wherein the plurality of plugs of the second tray are intermeshed with the plurality of sockets of the first tray, and the intermeshing of the plurality of plugs with the plurality of pockets retains the optical component within each of the pockets.

16. The assembly of claim 13, further comprising a retaining feature extending from each of the plurality of plugs, wherein the retaining feature is configured to engage with the optical component.

17. The tray of claim 13, wherein the dispersed carbon phase includes carbon fibers.

18. The tray of claim 13, wherein the dispersed carbon phase includes carbon nanotubes.

19. The tray of claim 13, wherein the optical component includes a compound parabolic concentrator, polarizing beam splitter, metallic RF shield, RGB die, CMOS die, MEMS, lens, or lens holder.

20. A method for using an optical component storage tray, comprising:
retaining an optical component in a pocket of a first optical component storage tray;
removing a second optical component storage tray, wherein the second tray is stacked upon the first tray;
picking the optical component from a first position within the pocket;
moving the optical component to a second position; and
placing the optical component at the second position.

21. The method of claim 20, wherein removing the second optical component storage tray demeshes engaging features of a plurality of sockets of the second tray from mating features of a plurality plugs of the first tray, thereby allowing access to the plurality of sockets of the first tray.

22. The method of claim 20, wherein picking the optical component from the first position includes grasping the optical component with mechanical pincers.

23. The method of claim 20, wherein picking the optical component from the first position includes applying a vacuum to the optical component.

24. The method of claim 20, wherein picking the optical component from the first position includes coupling a magnet to the optical component.

25. The method of claim 24, wherein placing the optical component at the second position includes generating a magnetic field, thereby decoupling the magnet from the optical component.
